(19) United States
(12) Patent Application Publication
(10) Pub. No.: US 2026/0243801 A1
(43) Pub. Date: Aug. 20, 2026

(54) PROBE HEAD FOR TESTING SEMICONDUCTOR DEVICES

(71) Applicant: TSE CO., LTD., Cheonan-si, Chungcheongnam-do (KR)

(72) Inventors: Young Hun JU, Cheonan-si (KR); Yoon Young JIN, Cheonan-si (KR); Haslo Mi KWARK, Cheonan-si (KR)

(73) Assignee: TSE CO., LTD., Cheonan-si, Chungcheongnam-do (KR)

(21) Appl. No.: 19/164,349

(22) PCT Filed: Mar. 5, 2024
(86) PCT No.: PCT/KR2024/002783

§ 371 Date: Sep. 11, 2025

(30) Foreign Application Priority Data
Mar. 15, 2023 (KR) 10-2023-0033772

(51) Int. Cl. G01R 1/073; G01R 1/067

(52) U.S. Cl. CPC G01R 1/07342; G01R 1/06722; G01R 1/06733; G01R 1/06755

(57) ABSTRACT

A probe head for testing semiconductor devices includes an upper plate having an upper accommodating hole, a lower plate formed spaced apart from the upper plate and having a lower accommodating hole, and a probe coupled to the upper plate and the lower plate such that upper and lower sides thereof are respectively accommodated in the upper and lower accommodating holes, wherein the upper plates are formed in the Z-axis direction, the upper side of the probe is accommodated in the upper accommodating holes of the upper plates, and at least one of the upper plates is disposed to be offset in at least one of an X-axis direction, a Y-axis direction, and an XY-axis direction relative to at least one of the remaining upper plates.

### CROSS REFERENCE TO RELATED APPLICATIONS

This application is a National Stage of International Application No. PCT/KR2024/002783 filed on Mar. 5, 2024, claiming priority based on Korean Patent Application No. 10-2023-0033772 filed on Mar. 15, 2023.

### TECHNICAL FIELD

The present disclosure relates to a probe head for testing semiconductor devices, which induces the side force on a probe, causing the probe to be constrained in a z-axis direction.

### BACKGROUND ART

In general, the manufacturing process of semiconductor devices includes a patterning process of manufacturing semiconductor devices, an electrical die sorting (EDS) process of electrically testing the semiconductor devices to determine whether the semiconductor devices are defective, and an assembly process of integrating the semiconductor devices on a wafer.

In the EDS process, each semiconductor device is supplied with a test current and the electrical signal output from the device is tested to determine whether the device is defective, and a probe device that electrically contacts a probe to each semiconductor device to test its performance is widely used.

Such a probe device includes a tester that supplies a test current to examine and analyze the resulting signal, a probe card that electrically connects the tester to a test object to be tested (semiconductor device), and a probe that is in direct contact with the test object and a printed circuit board of the probe card.

The probe is typically provided in a probe head structure with a plurality of probes housed therein to ensure reliable contact with the test object and the probe card while maintaining adequate contact pressure, and to ensure durability for multiple tests.

Generally, the probe head includes probes and a block in which the probes are housed, wherein the first and second ends of the probe are housed to protrude outwardly from the first and second faces of the block to electrically contact the printed circuit board and contact terminals of a semiconductor device, respectively, at an appropriate pressure.

Such a block includes an upper plate supporting an upper side of the probe and a lower plate supporting a lower side of the probe, wherein the upper and lower plates are formed in a structure spaced apart by a certain distance for stable support of the probe.

The upper plate and the lower plate are formed in a structure in which accommodating holes are formed with a pitch spacing corresponding to the contact terminals of the semiconductor device to be tested so that the probes are accommodated and assembled in the accommodating holes, and upon the test, the probes slide inside the accommodating holes by a predetermined pressure during the test.

In such a structure, the probes slide in the accommodating holes while contacting the printed circuit board and the contact terminals of the semiconductor device, but the probes lack constraining force in the Z-axis direction. In particular, due to manufacturing tolerances of the probe or machining deviations of the accommodating hole, the constraining force in the Z-axis direction of the probe is uneven, resulting in poor contact stability and accuracy of the probe.

In addition, due to limitations in fine-tuning by machining and assembly tolerances, a conventional probe and plate assembly Structure is not only unfavorable for maintaining uniform characteristics of multiple probes, but also suffers from further uneven characteristics among probes due to the lack of constraining force in the lateral direction, which causes play due to the weight of the probe, reducing contact stability.

The foregoing is intended merely to aid in the understanding of the background of the present disclosure, and is not intended to mean that the present disclosure falls within the purview of the related art that is already known to those skilled in the art.

### DISCLOSURE

### Technical Problem

Accordingly, the present disclosure has been made keeping in mind the above problems occurring in the related art, and an objective of the present disclosure is to a probe head for testing semiconductor devices, in which an upper plate is disposed to be offset to cause a side force to constrain a probe in the Z-axis direction, thereby improving the contact stability, accuracy, and uniformity of the probe.

### Technical Solution

In order to achieve the above objective, according to one aspect of the present disclosure, there is provided a probe head for testing semiconductor devices, the probe head including: an upper plate having an upper accommodating hole formed therein; a lower plate formed spaced apart from the upper plate and having a lower accommodating hole formed therein; and a probe coupled to the upper plate and the lower plate such that upper and lower sides thereof are respectively accommodated in the upper and lower accommodating holes with a body part thereof disposed between the upper plate and the lower plate, wherein the plurality of upper plates are formed in the Z-axis direction, the upper side of the probe is accommodated in the upper accommodating holes formed in the upper plates, and at least one of the upper plates is disposed to be offset in at least one of an X-axis direction, a Y-axis direction, and an XY-axis direction relative to at least one of the remaining upper plates to cause a side force on the upper side of the probe to constrain the probe in the Z-axis direction. Further, the plurality of upper plates may be offset from each other in any one of the X-axis direction, the Y-axis direction, and the XY-axis direction to deform the body part of the probe to allow a reaction force to be transferred to the upper side of the probe.

Further, the upper and lower plates may be arranged to be offset.

Moreover, the offset between the plurality of upper plates may preferably range from 5 μm to 100 μm.

Further, when the upper plate has top and bottom plates, the offset between the top plate and the bottom plate may preferably range from 10 μm to 50 μm.

Furthermore, the upper side of the probe may be formed with the following deformation parts to control the side force.

The upper side of the probe may be formed in a porous structure.

Further, the upper side of the probe may be formed in a single-slot or multi-slot structure, or a multi-slot structure with one or more bridges formed between multiple slots. Further, the upper side of the probe may be formed in a multi-slot structure in which at least one of slots has at least one curved surface, or has curved surfaces with different radii of curvature.

Further, the upper side of the probe may be formed in a multi-slot structure in which each slot has one or more protrusions, or a multi-slot structure in which at least one slot has a different width.

Further, the upper side of the probe may include at least one protrusion.

Further, the upper side of the probe may include at least one curved surface.

Preferably, the upper side of the probe may be formed in a dissimilar material structure having a higher strength material at an outer layer compared to an inner layer thereof, or may be formed in a dissimilar material structure having a higher strength material at upper and lower ends compared to a middle region thereof.

Preferably, the amount of allowable overdrive (OD) of the probe may be formed to be 200 μm or more, or the side force of the probe may range from 0.4 gf to 0.8 gf.

### Advantageous Effects

According to the probe head for testing semiconductor devices, the plurality of upper plates is arranged mutually offset from each other to generate a side force to constrain the probe in the Z-axis direction, thereby improving the contact stability, accuracy, and uniformity of the probe.

Furthermore, the degree of offset of the upper plates is adjusted to deform the body part of the probe so that the reaction force is transferred to the upper side of the probe, thereby increasing the average reaction force of the probe and promoting uniformity of characteristics between probes.

In addition, the deformed part (shape deformation, porous structure, slot structure, material deformation) is formed on the upper side of the probe that mates with the upper plate such that the side force is controlled with setting of the offset range of the upper plate or with change in the position due to the shape of the probe, thereby alleviating the processing and assembly tolerance generated by the probe and plate assembly structure to maintain uniform characteristics among multiple probes.

### DESCRIPTION OF DRAWINGS

FIGS. 1 and 2 are schematic views illustrating a probe head for testing semiconductor devices according to embodiments of the present disclosure;

FIGS. 3A, 3B and 3C are schematic views illustrating an upper side of a probe according to various embodiments of the present disclosure;

FIGS. 4A, 4B, 4C, 4D, 4E, 5A, 5B and 5C are schematic views illustrating deformed portions of the upper side of the probe according to various embodiments of the present disclosure;

FIGS. 6A to 6D are diagrams illustrating simulation results for stress distribution in the upper side of the probe upon application of an offset;

FIGS. 7A and 7B are diagrams illustrating the deformation in the probe body part (a) before applying the offset and (b) after applying the offset between the upper plates according to embodiments of the present disclosure;

FIGS. 8A to 8C are diagrams illustrating the reaction force and stress distribution as a function of the number of slots in the upper side of the probe according to embodiments of the present disclosure;

FIG. 9 is a diagram illustrating the relationship between the side force and the magnitude of the allowable offset as a function of the number of slots according to the embodiment of FIGS. 7A and 7B; and

FIGS. 10A, 10B, 10C and 10D are diagrams illustrating the magnitude of the side force and the degree of uniformity in the z-axis direction of the probe applied to the probe according to the conventional structure and to the structure of the embodiment of the present disclosure.

### BEST MODE

The present disclosure is directed to a probe head for testing semiconductor devices in which a plurality of upper plates is arranged mutually offset from each other to generate a side force so that the probe is constrained in the Z-axis direction, thereby improving the contact stability, accuracy, and uniformity of the probe.

Furthermore, the probe body part is deformed according to the side force generated by adjusting the offset degree of the upper plate or deforming the shape of the probe, and the resultant reaction force is transferred to further increase the constraining force in the Z-axis direction of the probe and increase the average reaction force of the probe, thereby further promoting uniformity of characteristics among probes.

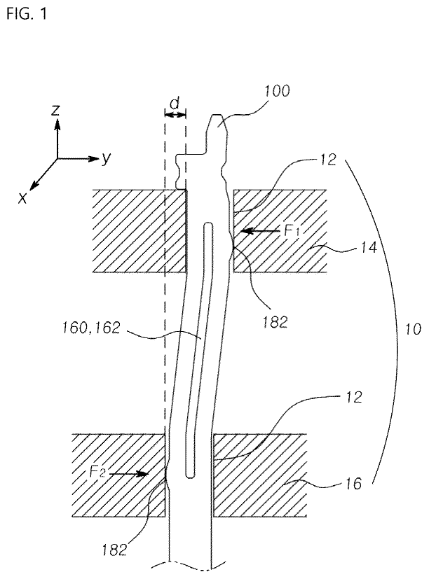

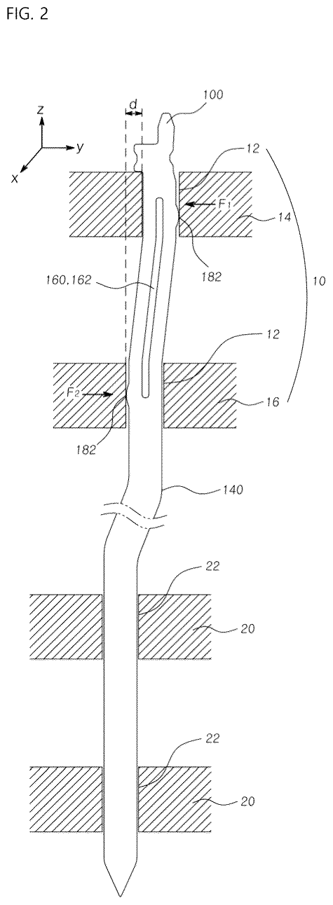

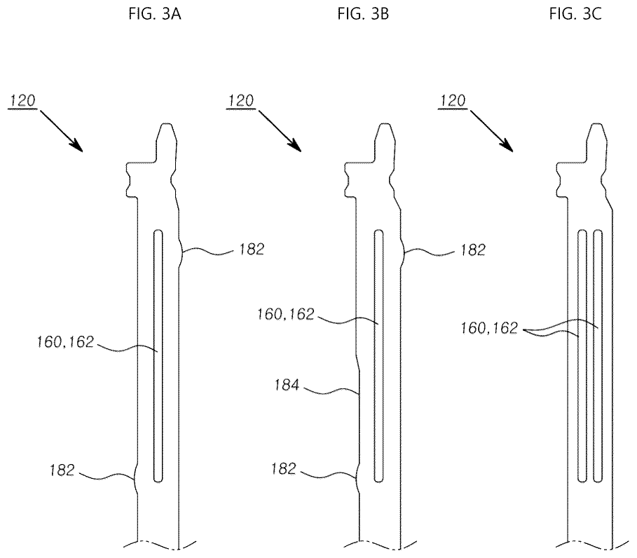

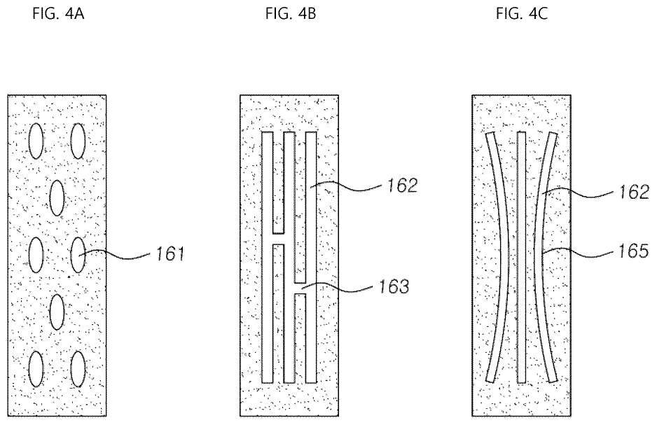

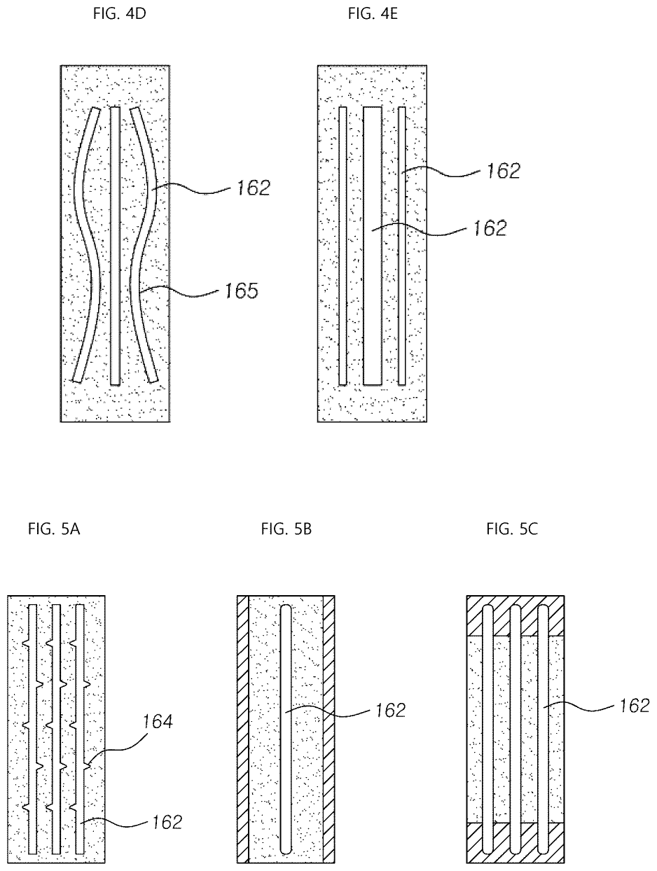

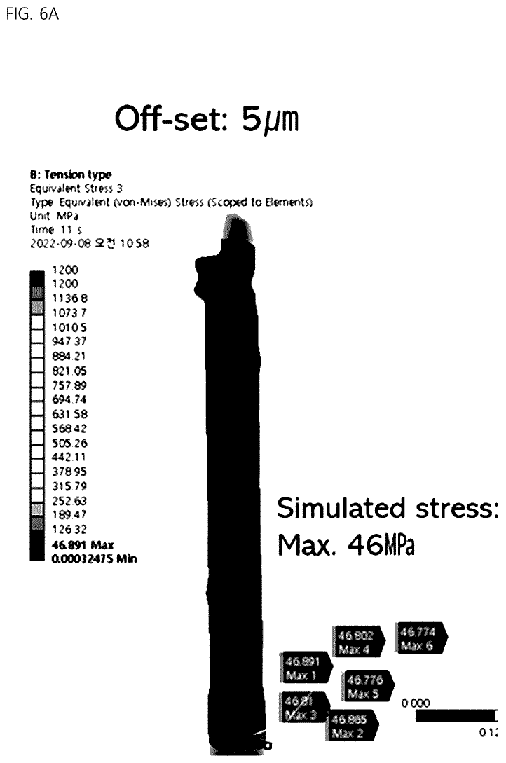

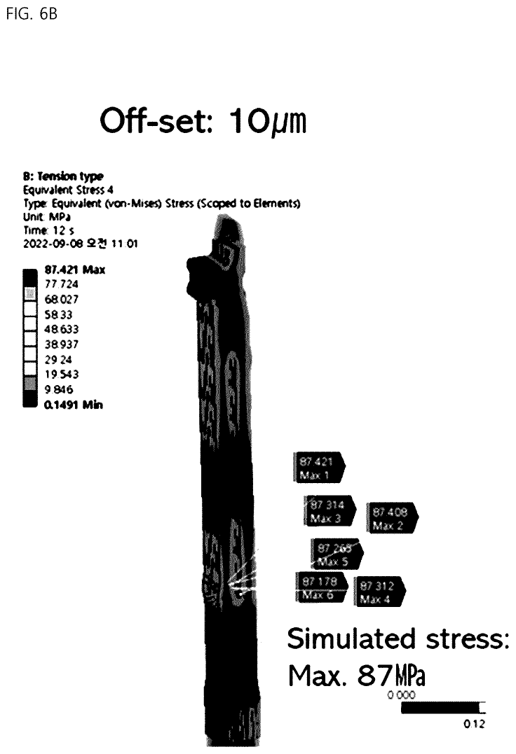

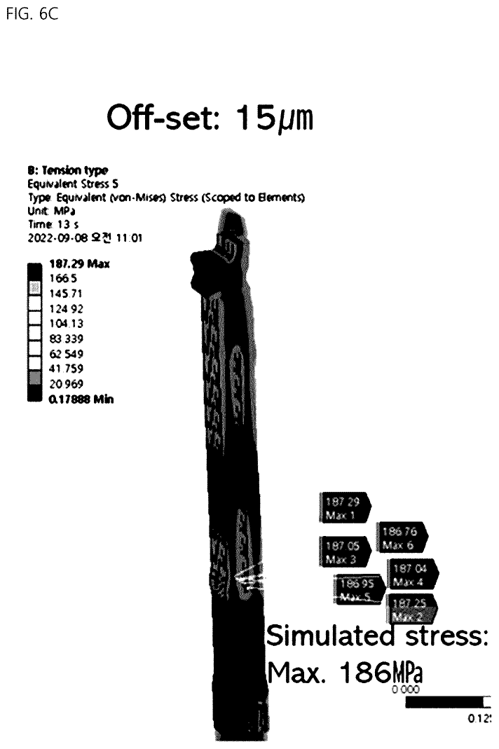

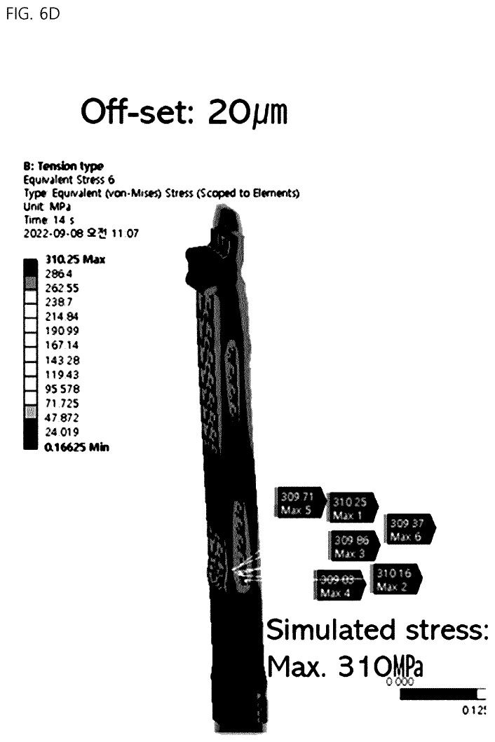

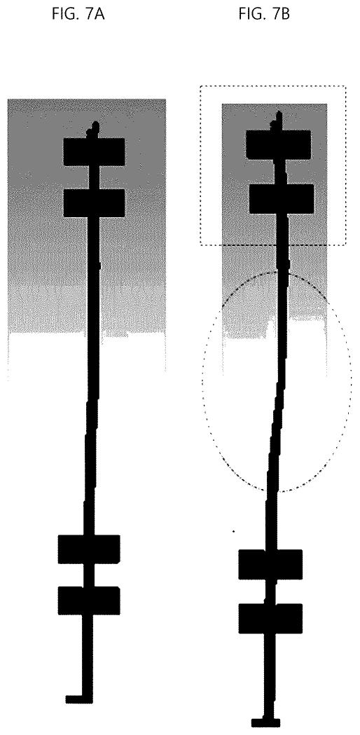

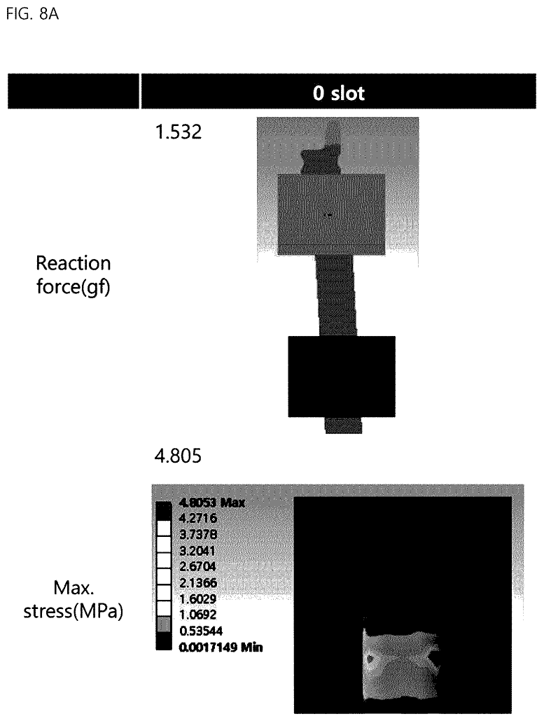

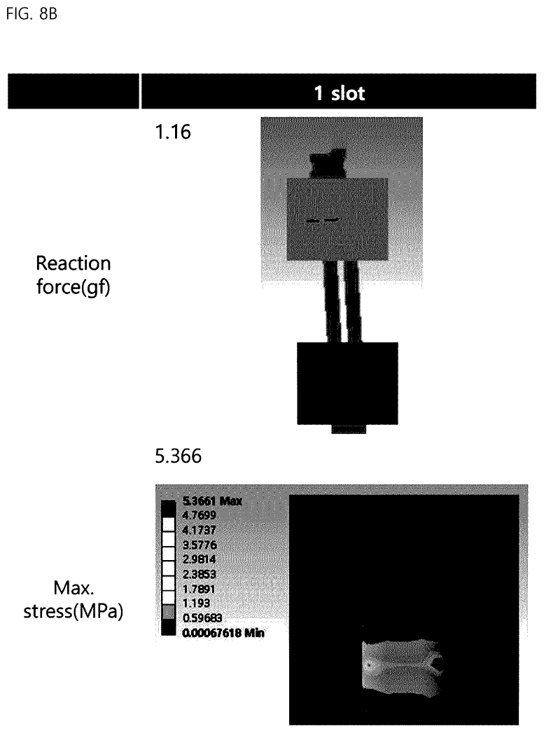

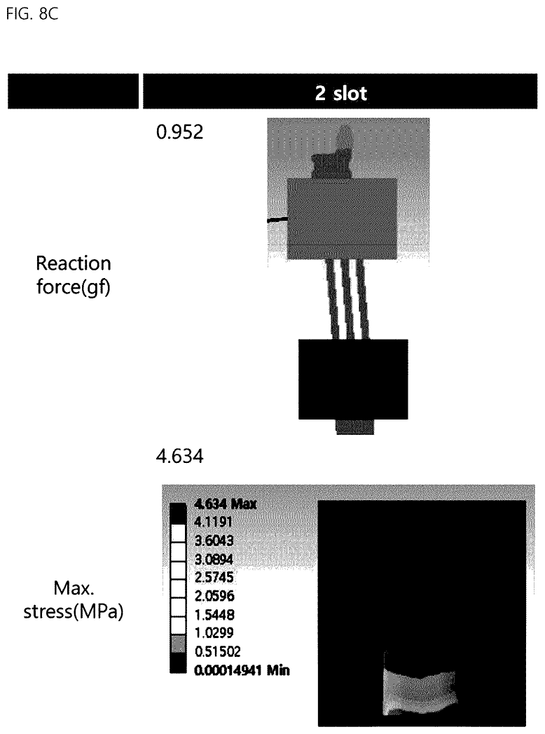

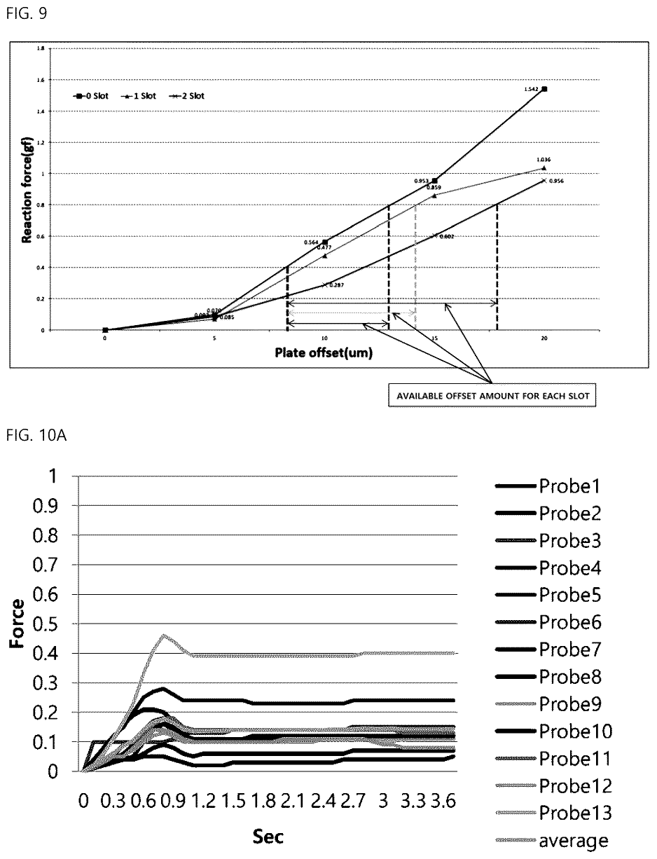

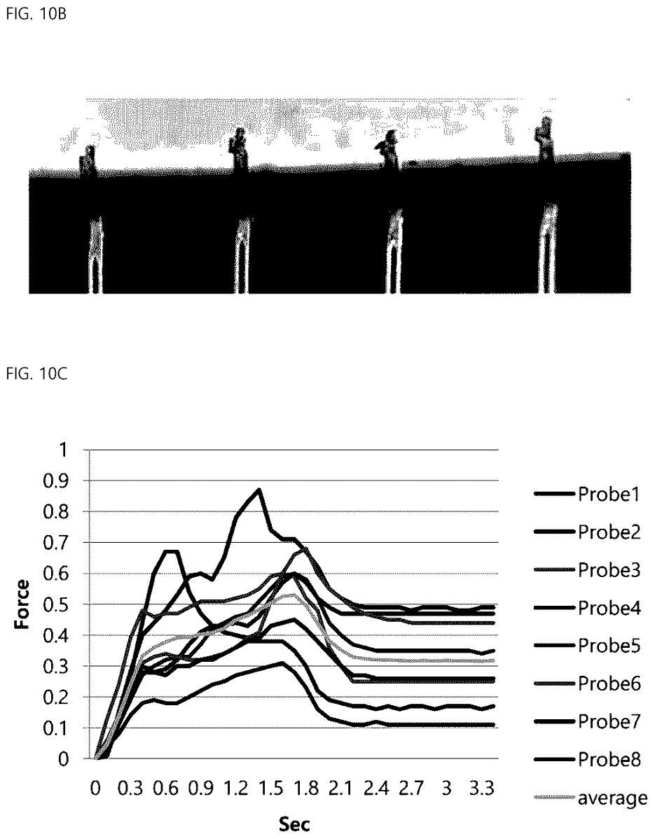

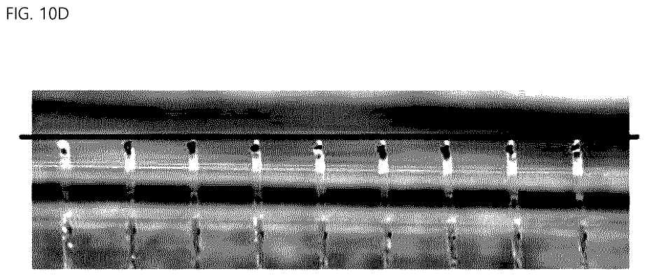

Hereinafter, embodiments of the present disclosure will be described in detail with reference to the accompanying drawings. FIGS. 1 and 2 are schematic views illustrating a probe head for testing semiconductor devices according to embodiments of the present disclosure, FIGS. 3A, 3B and 3C are schematic views illustrating an upper side of a probe according to various embodiments of the present disclosure, FIGS. 4A, 4B, 4C, 4D, 4E, 5A, 5B and 5C are schematic views illustrating deformed portions of the upper side of the probe according to various embodiments of the present disclosure, FIGS. 6A, 6B, 6C and 6D are diagrams illustrating simulation results for stress distribution in the upper side of the probe upon application of an offset, FIGS. 7A and 7B are diagrams illustrating the deformation in the probe body part (a) before applying the offset and (b) after applying the offset between the upper plates according to embodiments of the present disclosure, FIGS. 8A, 8B and 8C are diagrams illustrating the reaction force and stress distribution as a function of the number of slots in the upper side of the probe according to embodiments of the present disclosure, FIG. 9 is a diagram illustrating the relationship between the side force and the magnitude of the allowable offset as a function of the number of slots according to the embodiment of FIGS. 7A, 7B, and FIGS. 10A, 10B, 10C and 10D are diagrams illustrating the magnitude of the side force and the degree of uniformity in the z-axis direction of the probe applied to the probe according to the conventional structure and to the structure of the embodiment of the present disclosure.

As illustrated, the probe head for testing semiconductor devices according to embodiments of the present disclosure includes an upper plate 10 having an upper accommodating hole 12, a lower plate 20 formed spaced apart from the upper plate 10 and having a lower accommodating hole 22, and a probe 100 coupled to the upper plate 10 and the lower plate 20 so that upper and lower sides thereof are respectively accommodated in the upper lower accommodating holes with a body part 140 thereof disposed between the upper plate 10 and the lower plate 20. The plurality of upper plates 10 are formed in the Z-axis direction, the upper sides 120 of the probes are accommodated in the upper accommodating holes 12 formed in the upper plates 10, and at least one of the plurality of upper plates 10 is disposed to be offset in at least one of an X-axis direction, a Y-axis direction, and an XY-axis direction relative to at least one of the remaining upper plates 10 to cause a side force on the upper side 120 of the probe to constrain the probe 100 in the Z-axis direction.

Generally, the probe head for testing semiconductor devices includes the upper plates 10 and the lower plates 20 to accommodate and guide the probe 100, and the upper plates 10 and the lower plates 20 may be formed in the Z-axis direction to adjust or control the force applied to the probe 100 depending on the shape of the probe 100.

Furthermore, thousands to tens of thousands of probes 100 may be accommodated in the accommodating holes (upper accommodating holes 12, lower accommodating holes 22) of the upper plates 10 and the lower plates 20 to perform the test. For convenience, the present disclosure will be described with reference to a single probe 100 coupled to the upper plate 10 and the lower plate 20.

The probe head according to the embodiment of the present disclosure includes the upper plate 10 having the upper accommodating hole 12, the lower plate 20 formed spaced apart from the upper plate 10 and having the lower accommodating hole 22, and the probe 100 accommodated in the upper plate 10 and the lower plate 20 so that the upper and lower sides thereof are respectively accommodated in the upper and lower accommodating holes 12 and 22 with the body part 140 disposed between the upper plate and the lower plate 20.

The probe 100 may be formed of an elastic metal or metal composite material or the like having an elastic force. The probe is a needle-type pin with an upper tip protruding upwardly from the upper plate 10 and a lower tip protruding downwardly from the lower plate 20, and is deformed between the upper plate 10 and the lower plate 20 to reliably contact the contact terminals of the printed circuit board and the test object to be inspected.

Here, the upper plates 10 are formed in the Z-axis direction, the upper side 120 of the probe is accommodated in the upper accommodating holes 12 formed in the upper plates 10, and at least one of the plurality of upper plates 10 is disposed to be offset in at least one of an X-axis direction, a Y-axis direction, and an XY-axis direction relative to at least one of the remaining upper plates 10 to cause a side force on the upper side 120 of the probe to constrain the probe 100 in the Z-axis direction.

In the conventional probe-plate assembly structure, since the constraining force in the Z-axis direction lacks due to the assembly tolerance between the probe and the plate or the buckling characteristic due to the contact pressure between the printed circuit board and the test object, the probe floats inside the accommodating hole of the plate, causing a problem of deterioration in the contact stability, accuracy, and uniformity of the probe. In addition, there is a problem in that the contact between the probes is uneven, resulting in a decrease in the accuracy or precision of the test.

The present disclosure adjusts the offset of the plurality of the upper plates 10 from each other to cause a side force on the upper side 120 of the probe to constrain the probe 100 in the z-axis direction, thereby minimize the void between contact pads due to warpage of a spatial transformer itself in contact with the probe 100, preventing a separating phenomenon to improve the contact stability, accuracy, and uniformity of the probes 100, and improving the contact uniformity between the plurality of probes 100.

According to an embodiment of the present disclosure, the plurality of upper plates 10 are disposed to be offset in any one of the X-axis direction, the Y-axis direction, and the XY-axis direction, so that a side force is applied to the probe upper side 120 to constrain the probe 100 in the Z-axis direction.

In other words, the plurality of upper plates 10 are offset in the horizontal direction to apply a horizontal load to the probe upper side 120, which results in a horizontal reaction force (side force). Depending on the material, shape, and structure of the probe upper side 120, the side force may be controlled, and the horizontal load caused by the side force and the offset may induce elastic deformation in the probe upper side 120, which causes deformation of the probe 100 as a whole, particularly the probe body part 140.

In particular, by implementing a probe shape or material modification, i.e., a deformed part (shape modification, porous structure, slotted structure, material modification, etc.) 160 for controlling a side force on the probe upper side 120, the side force may be controlled, and the degree of elastic deformation induced in the probe upper side 120 may be controlled accordingly, and the deformation of the probe body part 140 may be coordinated with each other.

Here, the deformation of the probe body part 140 induces a reaction force transfer to the probe upper side 120, thereby increasing the average reaction force of the probe 100 and thus equalizing the constraint force along the z-axis direction of the probe and improving the uniformity of the characteristics of the probe 100 among the probes.

As exemplary embodiments of the present disclosure, FIGS. 1 and 2 illustrate a case where the upper plate 10 includes a top plate 14 and a bottom plate 16, and the lower plate 20 includes a top plate and a bottom plate, so each of the upper plate 10 and the lower plate 20 includes two plates.

According to the embodiment illustrated in FIGS. 1 and 2, the upper plate 10 and the lower plate 20 are offset on the whole, and in particular, the present disclosure illustrates that the two upper plates (top plate 14 on the upper side and bottom plate 16 on the lower side) 10 are offset by d in the horizontal direction.

FIGS. 1 and 2 illustrate the two top plates 10 being offset by d (in any one of the X-axis direction, the Y-axis direction, and the XY-axis direction) in accordance with one embodiment of the present disclosure, such that horizontal reaction forces (side forces) F1, F2 act on the probe upper side 120.

Here, F1, F2 may be of the same magnitude, different magnitudes, or only one of F1 and F2 may be provided. This will be influenced by the deformed part 160 formed in the probe 100, the overall shape of the probe 100, and the degree of offset.

In other words, by allowing the side forces F1, F2 to act on the probe upper side 120 so that the probe 100 is constrained in the Z-axis direction, elastic deformation is induced in the probe upper side 120 by the horizontal load and side forces depending on the offset between the upper plates 10, allowing the optimal offset range of the upper plates 10 to be set and the side forces to be controlled.

Furthermore, the elastic deformation in the probe upper side 120 results in deformation of the entire probe 100, particularly the probe body part 140 (see FIG. 2), and this deformation force is transferred back to the probe upper side 120 as a reaction force, which serves to increase the average reaction force of the entire probe 100. This increase in average reaction force may improve the uniformity of contact between the plurality of probes 100.

Furthermore, such an offset between the probe 100 and the upper plate 10 may mitigate machining deviations and assembly deviations of the probe 100 and the upper plate 10, thereby contributing to stability of the probe and uniform contact characteristics between the probes.

In one embodiment of the present disclosure, the offset between the plurality of upper plates 10 may be formed in the range of 5 μm to 100 μm, and in the case of an embodiment in which the upper plate 10 has top and bottom plates, the offset between the top plate 14 on the upper side and the bottom plate 16 on the lower side is preferably formed in the range of 10 μm to 50 μm.

If the offset exceeds the above range, the friction force between the probe and the plate increases due to the excessive offset, which may cause the constraining force of the probe to be excessive and prevent stable contact, or may cause the durability to be reduced due to wear of the plate or the probe, and if the offset falls short of the above range, the effectiveness of the transfer of the side force and the side force occurring due to the offset is insufficient to exert a stable constraining force in the Z-axis direction of the probe.

On the other hand, according to the present disclosure, the probe upper side 120 may be implemented with various deformed parts 160 to control the side force, and is illustrated in various embodiments as illustrated in FIGS. 3A to 3C, 4A to 4E, and 5A to 5C. These deformed parts 160 are not limited to the above embodiments, but may be formed in any shape, structure, or material for deforming the probe body part 140 so that the horizontal load and the side force due to the offset of the upper plate 10 act organically to elastically deform and control the side force.

As illustrated, the deformed part 160 of the probe upper side 120 according to one embodiment of the present disclosure may be formed as a porous structure 161 or may include at least one or more protrusions 161 formed to protrude from a sidewall of the probe upper side 120.

The load and side force caused by the offset between the probe upper side 120 and the upper plate 10 will be influenced by the porous structure 161 and protrusions 140 of the probe upper side 120, thereby providing a reference for establishing an appropriate usable offset without overloading the probe 100.

This, in turn, affects the side force between the probe and the plate, which in turn causes deformation in the probe 100 as a whole or in the probe body part 140, which in turn causes an interaction that transfers the side force to the probe upper side 120, thereby increasing the average reaction force between the probes 100 and further promoting uniformity of characteristics between the probes 100.

Furthermore, this structure of the probe 100 may adjust the offset range of the probe 100 and the upper plate 10 through the interaction and transition between the average reaction force and the side force, thereby mitigating machining deviations and assembly deviations, which further contributes to maintaining uniform characteristics between the probes 100.

FIGS. 3A, 3B and 3C illustrate various embodiments of the probe upper side 120 having a deformed part formed, wherein a single slot 162 is formed in the probe upper side 120 and a protrusion 140 is formed from the outer wall (FIGS. 3A, 3B), or multiple slots 162 are formed (FIG. 3C). In particular, FIG. 3B illustrates a curved portion 160 formed in conjunction with the protrusion 140.

This mitigates machining and assembly deviations and promotes uniformity characteristics among probes, depending on the interaction between mean reaction force and side force, as described above. The shape and number of these slots, protrusions, and curves may be formed in various combinations, and may be determined by the overall shape of the probe 100 and the amount of offset.

FIGS. 4A, 4B, 4C, 4D, 4E, 5A, 5B and 5C illustrate various embodiments of the deformed part 160 formed on the probe upper side 120. FIG. 4A illustrates a circular porous structure 161, and FIG. 4B illustrates a multi-slot structure having multiple slots 162 and one or more bridges 163 connecting the slots 162. FIGS. 4C and 4D illustrate a multi-slot structure in which at least one of the slots 162 includes a curved surface 165 having one or more equal or different radii of curvature. FIG. 4E illustrates a multi-slot structure, wherein at least one of the slots 162 has different widths.

In this way, by implementing deformed parts 160 such as various porous structures, slot structures, and protrusions in the region of the side forces and offset at the probe upper side 120, that is, between the probe 100 and the upper plate 10, the average reaction force on the probe 100 is regulated and interaction between the side forces is induced, so that the constraining force in the z-axis direction of the probe 100 may be further stabilized.

In particular, the multi-slot structure with curved surfaces 165 allows the horizontal load and side forces due to the offset to be distributed on the whole, and the degree of deformation of the probe body part 140 to be regulated accordingly, thereby enabling the range of available offsets to be adjusted to mitigate tolerances due to machining and assembly deviations.

In the embodiment of FIG. 4C, a concave portion is formed in the slots 162 formed on the outer side of the probe upper side 120 to provide greater (bending) strength to the outer side of the probe upper side 120, thereby further stabilizing or increasing the side forces in the multi-slot structure. FIG. 4D illustrates further uniformization of these side forces, and FIG. 4E illustrates a structure that further stabilizes or increases the side forces in the multi-slot structure by making the slots 162 narrower in width outwardly of the probe upper side 120 to increase the bending strength outwardly of the probe upper side 120.

FIG. 5A illustrates the multi-slot structure with one or more protrusions 164 formed in each slot 162, and FIGS. 5B and 5C illustrate the multi-slot structure with the probe upper side 120 formed of different materials. FIG. 5B illustrates the probe upper side 120 formed of different materials in the inner and outer layers of the probe upper side 120. In one embodiment, the outer layer has a higher strength than the inner layer. FIG. 5c illustrates that the upper and lower ends of the probe upper side 120 are formed of different materials, and in one embodiment, the upper and lower ends have a higher strength than the middle region of the probe upper side 120.

The structure of the probe upper side 120 of FIGS. 5A, 5B and 5C is intended to distribute the side forces on the probe as a whole, and to induce deformation of the probe body part 140 to adjust the range of available offsets, thereby allowing tolerances for machining and assembly variations to be mitigated.

FIGS. 5B and 5C illustrate a structure that provides greater bending strength outwardly of the probe upper side 120, or greater bending strength at either the upper or lower end of the probe upper side 120, to increase the side force and further stabilize the side force.

In this way, by forming the deformed part 160 in the probe upper side 120 in the region where the horizontal load and the side force act due to the offset between the upper plates 10, a side force is generated in the probe upper side 120, thereby causing an interaction that induces a transition of the reaction force upon deformation of the probe body part 140, thereby establishing a usable offset range and increasing the average reaction force of the probe 100, thereby allowing for relaxation of design and machining tolerances and improved characteristic uniformity among the probes 100.

To this end, one embodiment of the present disclosure may be implemented with various combinations of deformed parts 160, such as porous structures, protrusions, slotted structures, dissimilar materials, and the like.

According to one embodiment of the present disclosure, the amount of allowable overdrive (O/D) of the probe 100 (the distance at which the first probe contacts the contact terminal and all the remaining probes are in contact) is 200 μm or more, which may correspond to warpage in multi-layer organic (MLO) (e.g., spatial transformer), and the side force of the probe is 0.4 gf to 0.8 gf, so that the characteristics of the probe are uniform among the probes, and the constraining force in the Z-axis direction of the probe prevents the probe from floating or dropping due to its own weight, contributing to the stabilization of the characteristics of the probe while promoting the uniformization of the characteristics.

In the following, various experimental examples using embodiments of the present disclosure will be described.

FIGS. 6A, 6B, 6C and 6D illustrate the stress distribution on the upper side of the probe as a function of the offset between the upper plates, wherein FIG. 6A shows an offset of 5 μm, FIG. 6B shows an offset of 10 μm, FIG. 6C shows an offset of 15 μm, and FIG. 6D shows an offset of 20 μm.

As illustrated in FIGS. 6A, 6B, 6C and 6D, the offset between the upper plates resulted in a stress distribution on the upper side of the probe, and as the offset increases, the stress increases further.

For an offset of 5 μm, almost no stress occurred, and for an offset of 20 μm, a maximum allowable stress of 310 MPa was observed. This is about one-third of the safe stress range allowed by the probe material, where the applied offset condition does not cause plastic deformation of the probe, which would otherwise result in damage to the probe or excessive wear of the plate.

Thus, in one embodiment of the present disclosure, an offset of 10 μm to 50 μm may be appropriate, and the adjustment of this offset may be determined by implementing the deformed part 160 with respect to the optimal shape and material of the upper side of the probe for controlling the side force.

FIGS. 7A and 7B illustrate the deformation of the probe body part 140 (a) before applying the offset between the upper plates and (b) after applying the offset (15 μm) between the upper plates in accordance with one embodiment of the present disclosure where the probe body part 140 is deformed by the side force due to the application of the offset between the upper plates, which in turn transfers the side force to the probe upper side, thereby increasing the average reaction force between the probes.

FIGS. 8A, 8B and 8C illustrate the distribution of reaction force and stress as a function of the number of slots in the probe upper side, in accordance with one embodiment of the present disclosure, and it can be seen that as the number of slots increases, the stress and reaction force decrease and the amount of offset available increases.

In this way, by implementing an offset between the upper plates and a deformed part (adjusting the number of slots) on the upper side of the probe, the stress may be controlled according to the control of the side force, and the available offset may be checked to ensure the safety and characteristic uniformity of the probe.

FIG. 9 illustrates the relationship between the magnitude of the offset according to the number of slots and the side force according to the embodiment of FIGS. 8A, 8B and 8C, and it can be seen that the amount of offset available increases as the number of slots increases, and adjustment of this amount of offset may mitigate the machining and assembly tolerance between the probe and the plate, further promoting characteristic uniformity among the probes.

FIGS. 10A, 10B, 10C and 10D illustrate the magnitude of the side force applied to the probe according to the conventional structure (a), (b) (no offset in the structure of FIG. 3B) and the embodiment of the present disclosure (structure (c), (d) with an offset of 15 μm between the upper plate and the lower plate 20 in the structure of FIG. 3B, and the degree of uniformity in the z-axis direction of the probe.

The measurement of the side force was performed by generating a play between a test jig and the probe head with a measurement overdrive (O/D)) of 50 μm or more, adjusting the reaction force extraction time of the evaluation facility to 0.1 s, and applying the O/D at the upper tip position of the probe to check the reaction force value over time.

As illustrated in FIGS. 10A and 10B, in the conventional structure, the average reaction force between the probes is as low as 0.14 gf, which results in a low and uneven side force of the probe, causing the probe to play due to its own weight, which reduces the stability of the contact characteristics. In addition, the amount of allowable O/D is 70 μm, which is insufficient to respond to warpage in MLO, resulting in insufficient stability, accuracy, and uniformity of contact characteristics.

As illustrated in FIGS. 10C and 10D, in the embodiment of the present disclosure, the average reaction force between the probes is 0.57 gf, and the characteristics between the probes are uniform as the side force rises, so that the drop caused by the weight of the probe is minimized, thereby promoting the stability of the contact characteristics. In addition, the amount of allowable O/D is 200 μm, which is suitable for responding to warpage in MLO, which may improve the stability, accuracy, and uniformity of contact characteristics.

In other words, the void between the contact pads due to the warpage of the spatial transformer itself in contact with the probe is minimized, and the separating phenomenon is prevented, thereby improving the contact stability, accuracy, and uniformity of the probe.

According to the probe head for testing semiconductor devices, the plurality of upper plates is arranged mutually offset from each other to generate a side force to constrain the probe in the Z-axis direction, thereby improving the contact stability, accuracy, and uniformity of the probe.

Furthermore, the degree of offset of the upper plates is adjusted to deform the body part of the probe so that the reaction force is transferred to the upper side of the probe, thereby increasing the average reaction force of the probe and promoting uniformity of characteristics between probes.

In addition, the deformed part (shape deformation, porous structure, slot structure, material deformation) is formed on the upper side of the probe that mates with the upper plate such that the side force is controlled with setting of the offset range of the upper plate or with change in the position due to the shape of the probe, thereby alleviating the processing and assembly tolerance generated by the probe and plate assembly structure to maintain uniform characteristics among multiple probes.

1. A probe head for testing semiconductor devices, the probe head comprising:
an upper plate having an upper accommodating hole formed therein;
a lower plate formed spaced apart from the upper plate and having a lower accommodating hole formed therein; and
a probe coupled to the upper plate and the lower plate such that upper and lower sides thereof are respectively accommodated in the upper and lower accommodating holes with a body part thereof disposed between the upper plate and the lower plate,
wherein the plurality of upper plates is formed in the Z-axis direction, the upper side of the probe is accommodated in the upper accommodating holes of the upper plates, and at least one of the upper plates is disposed to be offset in at least one of an X-axis direction, a Y-axis direction, and an XY-axis direction relative to at least one of the remaining upper plates to cause a side force on the upper side of the probe to constrain the probe in the Z-axis direction.

2. The probe head of claim 1, wherein the plurality of upper plates is offset from each other in any one of the X-axis direction, the Y-axis direction, and the XY-axis direction to deform the body part of the probe to allow a reaction force to be transferred to the upper side of the probe.

3. The probe head of claim 1, wherein the upper and lower plates are arranged to be offset.

4. The probe head of claim 1, wherein the offset between the plurality of upper plates ranges from 5 μm to 100 μm.

5. The probe head of claim 1, wherein when the upper plate has top and bottom plates, the offset between the top plate and the bottom plate ranges from 10 μm to 50 μm.

6. The probe head of claim 1, wherein the upper side of the probe is formed with a deformed part to control the side force.

7. The probe head of claim 6, wherein the upper side of the probe is formed in a porous structure.

8. The probe head of claim 6, wherein the upper side of the probe is formed in a single-slot or a multi-slot structure.

9. The probe head of claim 8, wherein the upper side of the probe has one or more bridges formed between slots.

10. The probe head of claim 8, wherein the upper side of the probe is formed in a multi-slot structure in which at least one of slots has at least one curved surface.

11. The probe head of claim 10, wherein the upper side of the probe has at least one slot with different radii of curvature of the curved surface.

12. The probe head of claim 8, wherein the upper side of the probe is formed in a multi-slot structure in which each slot has one or more protrusions.

13. The probe head of claim 8, wherein the upper side of the probe is formed in a multi-slot structure in which at least one slot has a different width.

14. The probe head of claim 6, wherein the upper side of the probe has at least one protrusion.

15. The probe head of claim 6, wherein the upper side of the probe has at least one curved surface.

16. The probe head of claim 6, wherein the upper side of the probe is formed in a dissimilar material structure having a higher strength material at an outer layer compared to an inner layer thereof.

17. The probe head of claim 6, wherein the upper side of the probe is formed in a dissimilar material structure having a higher strength material at upper and lower ends compared to a middle region thereof.

18. The probe head of claim 1, wherein the amount of allowable overdrive (OD) of the probe is formed to be 200 μm or more.

19. The probe head of claim 1, wherein, the side force of the probe ranges from 0.4 gf to 0.8 gf.
